(19) United States
(12) Patent Application Publication
(10) Pub. No.: US 2007/0173032 A1
(43) Pub. Date: Jul. 26, 2007

(54) Wafer dicing by channels and saw

(75) Inventors: Bruce David Gibson, Lexington, KY (US); Richard Michael Moore, Bardstown, KY (US)

Correspondence Address: LEXMARK INTERNATIONAL, INC.;INTELLECTUAL PROPERTY LAW DEPARTMENT, 740 WEST NEW CIRCLE ROAD, BLDG. 082-1, LEXINGTON, KY, 40550-0999, US

(73) Assignee: Lexmark International, Inc.

(21) Appl. No.: 11/338,989

(22) Filed: Jan. 25, 2006

(51) Int. Cl. H01L 21/30; H01L 21/46

(52) U.S. Cl. 438/455

(57) ABSTRACT

In a silicon wafer two channels are etched in each street separated enough to bracket the saw. The channels may be shallow. The saw blade is positioned within the two channels so that the outer wall of each of the channels is beyond the outer edge of the saw. Cracks and the like caused by the saw terminate at the channels and so the adjoining chips are not injured. Damage of chips is reduced and the width of the streets is reduced.

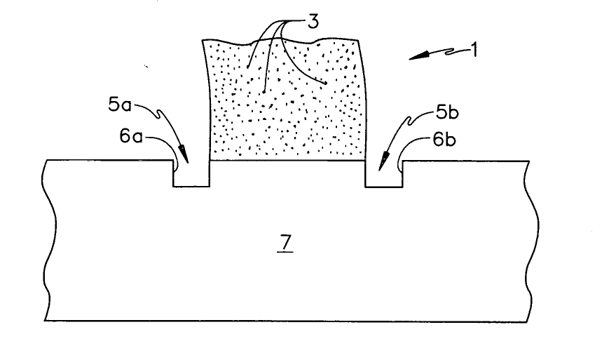

### TECHNICAL FIELD

This invention relates to the separation of silicon wafers into individual chips in a method which reduces the potential physical defects while increasing the surface area of the wafer which can be populated as final chips.

### BACKGROUND OF THE INVENTION

As is well established, silicon wafers are made which have a large number of chips populated for electrical function with the chips on the wafer separated by linear regions known as streets for singulating the chips of the wafer. Singulating (separating) the chips is commonly known as dicing. The use of a saw to dice the wafer is desirable for reasons of increased speed and reduced cost and complexity. However, the speed of movement of the saw is limited in practical use to prevent physical damage to the chips.

Etching is a low impact process and is known for use in such dicing with or without a sawing step. In such known prior art, the etching provides some of the penetration and the saw operation is continued on the same line as the previous penetration of the etch. A single etch penetration is used at each street which may be comparable in width to the width of the saw. The low-impact advantages of etching are realized, but actual implementation requires that the etching be fairly deep and wide, thus raising the speed, cost and complexity disadvantages. Also, when the etching process is being employed to form other features on the wafer, the depth of a wide etch is difficult to control.

This invention employs a recognition that the physical impact disadvantages of the saw primarily occur at the surface of entry and occur by radiating cracks or similar physical disturbances laterally. This invention employs a pattern of etched channels to contain and thereby neutralize such defects. As compared with saw-only dicing, this invention permits the streets to be much narrower, such as one-half as wide as the streets for saw-only dicing. As physical defects from the saw are contained, the speed of movement of the saw may be increased.

### DISCLOSURE OF THE INVENTION

In accordance with this invention two channels are etched in each street separated enough to bracket the saw. The channels may be shallow grooves, such as less then 50 microns in depth. The saw blade is positioned within the two channels so that the outer wall of each of the channels is beyond the outer edge of the saw. Cracks and the like caused by the saw terminate at the channels and so the adjoining chips are not injured. Preferably, at least the outer sides of the channels are generally perpendicular to the surface of the wafer so as to avoid sharp edges which are prone to fracture.

Great efficiencies are realized by reduction of damaged chips and reduction of the width of the streets while primarily using a saw to dice, which is quicker and less costly than etching deep into the wafer.

### BRIEF DESCRIPTION OF THE DRAWING

The details of this invention will be described in connection with the accompanying drawing, in which a wafer is shown in cross section, from a slight perspective, having shallow grooves bracketing a saw for dicing the wafer.

### DESCRIPTION OF THE PREFERRED EMBODIMENTS

As shown in the drawing, preferably the saw 1, shown illustratively with embedded abrasive grit 3 for cutting, such a diamond powder, is located between two, shallow grooves 5a and 5b in a silicon wafer 7. Grooves 5a and 5b are shown illustratively as square in cross section. Other cross sections having outer sides 6a and 6b which are generally perpendicular to the surface of wafer 7, such as trapazoidal, are preferred to avoid sharp angles, which are prone to fracture.

The position of saw 1 may very depending on tolerances and the width of the channels and saw in particular applications. Adequate functioning depends essentially only on saw 1 being between outer sides 6a and 6b.

Saw 1 extends entirely across wafer 7 and thereby severs wafer 7. As is conventional, the saw is moved through the streets of wafer 7 to thereby dice wafer 7 into separate chips (not shown). A typical saw 1 is 100 microns or less in width. A typical street absent this invention is 100 microns in width. With this invention the street width can be about 50 microns.

The chips have normally been previously populated as electrical devices. Where the chips are thermal inkjet chips, they may have also received a thin, polymer cover defining nozzle holes and some flow channels for ink. Normally, because of the need to apply elements of population, the wafer can not be diced prior to completion of much or all of the population of the chips.

Standard etching may be employed on the chips to form holes and chambers as required. This invention is particularly suited to the formation of chips where deep reactive ion etching is to be used to form via holes and other chamber in thermal inkjet chips. Since such etching is to be conducted, the addition of etching to form the dicing channels adds only small burden and expense. Additionally, with deep reactive ion etching, a narrow slit in the mask forming each channel results in shallow etching.

Although this invention is not limited to deep reactive ion etching, the excellent control of such etching does facilitate this invention. Deep reactive ion etching is described more fully in commonly-owned U.S. Pat. No. 6,613,687 B2 to Hart et al. An etching plasma gas is used, such as sulfur hexafluoride, and this is alternated in time with a passivating gas such as trifluoromethane. A lower substrate is electrified and the etching gas functions primarily in the direction of the substrate, although the etching is not fully anisotropic. (Anisotropic etching is not an important factor for the basic application of this invention.)

Since physical injury is contained by the bracketing channels, the speed of movement of the saw can be increased and the width of the streets can be reduced. The advantages of speed and costs of saw dicing are largely preserved.

Alternatives employing a pattern of etched channels can be employed.

What is claimed is:

1. A method of dicing a silicon wafer having streets for dicing said wafer into separated chips comprising
etching spaced apart channels in said streets, and then
completing dicing of said chips by sawing through said wafer in said streets by a saw located between the outer sides of said channels.

2. The method of claim 1 in which the depth of each of said channels is less than 50 microns.

3. The method of claim 1 in which the width of said streets is about 50 microns.

4. The method of claim 2 in which the width of said streets is about 50 microns.

5. The method of claim 1 in which said channels are etched to have outer sides which are generally perpendicular to the surface of said silicon wafer.

6. The method of claim 2 in which said channels are etched to have outer sides which are generally perpendicular to the surface of said silicon wafer.

7. The method of claim 3 in which said channels are etched to have outer sides which are generally perpendicular to the surface of said silicon wafer.

8. The method of claim 4 in which said channels are etched to have outer sides which are generally perpendicular to the surface of said silicon wafer.

9. The method of claim 1 in which said etching is by deep reactive ion etching.

10. The method of claim 2 in which said etching is by deep reactive ion etching.

11. The method of claim 3 in which said etching is by deep reactive ion etching.

12. The method of claim 4 in which said etching is by deep reactive ion etching.

13. The method of claim 5 in which said etching is by deep reactive ion etching.

14. The method of claim 6 in which said etching is by deep reactive ion etching.

15. The method of claim 7 in which said etching is by deep reactive ion etching.

16. The method of claim 8 in which said etching is by deep reactive ion etching.

17. A method of dicing a silicon wafers having streets for dicing said wafer into separated chips comprising
providing a silicon wafer having streets of about 50 microns in width,
providing a saw having width less than 50 microns,
etching spaced apart channels in said streets to have outer sides which are generally perpendicular to the surface of said silicon wafer and spaced apart more than the width of said saw, and
completing dicing of said chips by sawing through said wafer in said streets by said saw located between the outer sides of said channels.

18. The method of claim 1 in which the depth of each of said channels is less than 50 microns.

19. The method of claim 17 in which said etching is by deep reactive ion etching.

20. The method of claim 18 in which said etching is by deep reactive ion etching.
